(19) United States
(12) Patent Application Publication
(10) Pub. No.: US 2020/0153356 A1
(43) Pub. Date: May 14, 2020

(54) DETERMINISTIC GAS-PLASMA-REGULATED AUTO POLARITY HIGH-VOLTAGE ELECTRIC-FIELD TRANSDUCING TRANSFORMER

(71) Applicant: Yehoshua HADSHANI, Jerusalem (IL)

(72) Inventor: Yehoshua HADSHANI, Jerusalem (IL)

(21) Appl. No.: 16/633,057

(22) PCT Filed: Mar. 26, 2018
(86) PCT No.: PCT/IL2018/050347

§ 371 Date: Jan. 22, 2020

(30) Foreign Application Priority Data
Aug. 7, 2017 (IL) 253887

(51) Int. Cl. H02M 7/217; H02M 7/48; H02M 1/44

(52) U.S. Cl. CPC H02M 7/2176; H02M 1/44; H02M 7/48

(57) ABSTRACT

The invention allows for transformation to DC of electric fields of unknown or variable strength and polarity, using conventional, easily obtainable components. The device employs plasma arrestors, high voltage capacitors, a step-down transformer, filter capacitors, a bridge rectifier, smoothing capacitors, field-effect rectifier diodes and an intermediate storage capacitor bank to accomplish this.

### FIELD OF THE INVENTION

The invention relates to a novel step-down transformer adapted for use with high voltages and high-voltage fields of unknown densities, magnitudes and durations.

### BACKGROUND OF THE INVENTION

Step-down transformation of extremely high-voltage usually requires large, heavy, expensive and often complex apparatus, prone to failures due to any of a number of causes while operating both unloaded as well as under load including but not limited to dielectric failure, “spark over”, over-voltages, other material failures, etc.

Also, variable extremes of high-voltage/low-amperage step-down transformation, i.e., converting a high-voltage/low-amperage to a relatively low but more conventionally useful voltage with proportionally higher amperage presents additional complexities and problems similar to but not confined to those listed above. Possible high-voltage/high-amperage transient rises (also known as “surges” or “spikes”) are an additional common problem encountered that must be mitigated.

In addition to the aforementioned typical step-down transformation considerations, further factors that must be accounted for in order to effectively and efficiently transduce and transform electric fields include unknown or changing polarities, continuously variable electric-field densities as well as “transduction dropout”, ie, over-draw causing cessation of transduction whilst ample ambient electric-field potentials remain, etc., as is known to those skilled in the art.

CN102783027A discloses a high-voltage pulse generator capable of producing high-voltage electrical pulses at a high current utilizing efficient structure for generation, step-up transformation, storage and discharge of high-voltage electrical pulses. However, neither CN102783027A or any other publication in the prior art teaches, suggests or even hints the novel method for step-down transformation of high-voltage disclosed herein.

The present disclosure describes exemplary embodiments of inventive methods and apparatus enabling reliable and safe transduction, transformation, intermediate storage, and discharge to load, thereby enabling conventional usage of even extremely high-voltage electric possessing various voltage and potential current densities. Said exemplary embodiments are constructed from readily obtainable, COTS (commercial-of-the-shelf) parts, and can be clearly “scaled” for various useful purposes by direct inference from the present disclosure by one ordinarily skilled in the art. Additionally, this teaching provides a basic methodology for employing more specialized components in a similar manner for achieving the specified results.

As is well-known to those with ordinary skill in the art, various strategies employing common electrical and electronic principles and techniques are utilized to perform voltage/current step-down transformation, for a plurality of purposes, including but not limited to: measurement, monitoring, switching, power transmission (ie, from high-tension long-distance power lines to local users), etc. This transformation is almost always fairly straight-forward for AC (alternating current), and notably, is the major reason that AC was originally chosen over DC (direct current) for large-scale power generation and distribution. The reason is that magnetic transformers (already quite well understood at that time) can only directly transform AC; should DC need to be transformed, other techniques must be employed, for example: switching (such as in switch-mode power supplies), pulsing (such as pulse-width modulation techniques), capacitive voltage division, resistive voltage division, etc.

In the case of either AC or DC, transformation of higher voltages requires one or more of the following: heavier transformers, more dielectric (insulating) material, specialized and usually expensive and failure-prone high-voltage electronic components, etc.

In the aforementioned typical, conventional, existing AC and DC transformation systems, wherein the range of voltage and current levels are specified in advance, appropriate materials, including dielectrics/insulators and conductors, magnetics and electronics, etc., are readily chosen and employed.

However, transduction and transformation of electric fields ranging from low-voltage and current potentials to extremely high-voltage and current potentials is non-obvious, non-trivial and quite complex, even more so when the electric field may exhibit extremely unpredictable variability and unknown and/or variable polarity.

An electric field of unknown/variable strength, density and polarity clearly presents several extreme difficulties, including but not limited to: appropriate dielectric/insulating materials, optimal conductive materials, etc. as well as the obvious problems of achieving reliable and safe operation while keeping the size, weight, and complexity of the apparatus to a minimum, in order to allow consistent, reliable operation in a multiplicity of environments and for various purposes. Additionally, executing these capabilities using conventional, readily obtainable components would unquestionably be highly desirable, especially where such an apparatus is also able to transduce and transform conventional direct and/or alternating currents at appropriate frequencies (due to auto-polarity capability).

This disclosure describes exemplary, functional embodiments of methods and apparatus for achieving the aforementioned functionality.

### SUMMARY OF THE INVENTION

The present invention allows for transduction and transformation of electric fields of unknown or variable strength, density and polarity, as well as conventional direct and/or alternating currents at appropriate frequencies to usable direct current, using conventional, readily obtainable components.

A step-down transformer of the present invention is comprised of the following components: at least one pulse capacitor bank, a plurality of plasma arrestors (also known as “gas plasma arrestors” and “gas discharge tubes”), a high-voltage transformer, filter capacitors, a full wave bridge rectifier, smoothing capacitor(s), and an intermediate-storage capacitor bank. Additionally, two additional diodes are employed between said smoothing capacitor(s) and said intermediate-storage capacitor bank, for purposes including but not limited to effectively result in partial recovery of both signal-reflection [from charge-pulses] and so-called reactive power by means of phase-adjustment, varying impedance compensation, etc., resulting in effective efficiencies of greater than eighty percent.

The foregoing embodiments of the invention have been described and illustrated in conjunction with systems and methods thereof, which are meant to be merely illustrative, and not limiting. Furthermore just as every particular reference may embody particular methods/systems, yet not require such, ultimately such teaching is meant for all expressions notwithstanding the use of particular embodiments.

### BRIEF DESCRIPTION OF THE DRAWINGS

Embodiments and features of the present invention are described herein in conjunction with the following drawings:

FIG. 1 is a diagram of an exemplary embodiment of the present invention.

FIG. 2 is a schematic representation of an exemplary embodiment of the disclosed invention.

FIG. 3 is a chart depicting voltage accumulated in a capacitor component in an operating exemplary embodiment of the disclosed invention.

FIG. 3a is a chart depicting both the regulation of the High-Voltage input and the voltage accumulated in a capacitor component in an operating exemplary embodiment of the present invention, concurrently.

### DETAILED DESCRIPTION OF PREFERRED EMBODIMENTS

The present invention will be understood from the following detailed description of preferred embodiments, which are meant to be descriptive and not limiting. For the sake of brevity, some well-known features, methods, systems, procedures, components, circuits, and so on, are not described in detail.

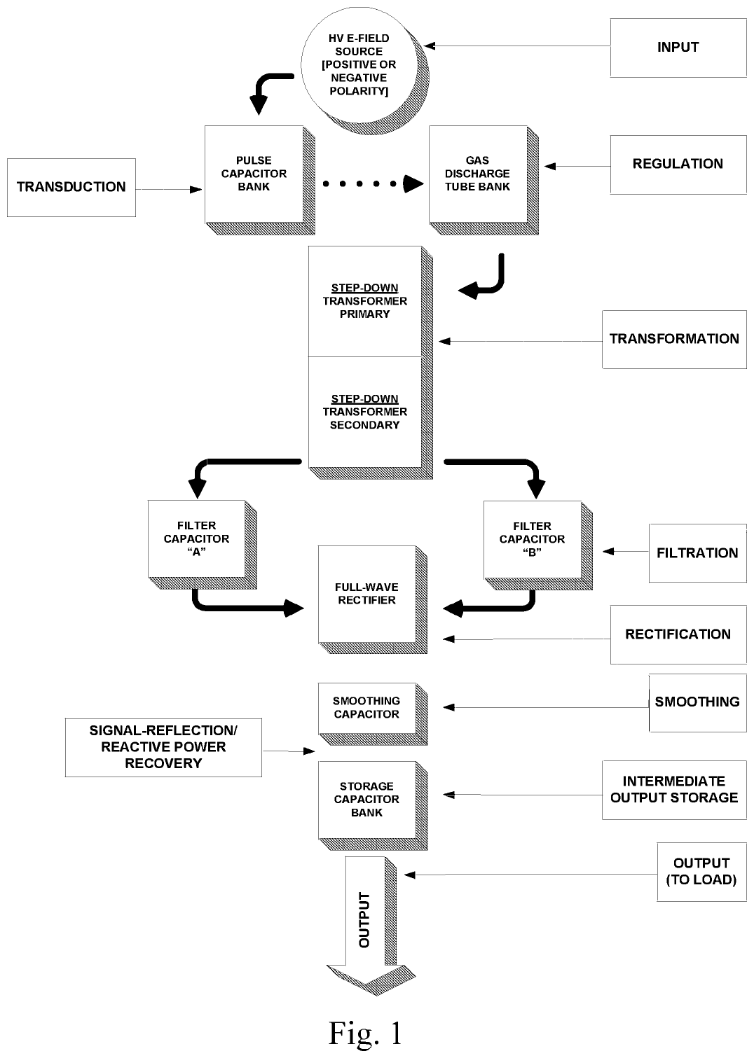

The method and apparatus for Deterministic Gas-Plasma-Regulated Auto-Polarity High-Voltage Electric-Field Transducing Transformer disclosed herein consists of the following elements, functionally described and illustrated in FIG. 1. The figure components are referred to by name.

The Input comprises an HV E-Field (High-Voltage Electric Field) Source [but will also function with an alternating and/or direct current source at appropriate frequency].

Transduction of the HV is accomplished via a pulse capacitor bank, rated to at least more than twice the predetermined regulated voltage (described below) for the purpose of withstanding damage to the capacitor bank due to frequency/voltage dependencies influencing capacitor bank parameters during operation, as well as allowing increased throughput and efficiency due to factors including, but not limited to improved tau (“τ”), also known as RC time constant, as is known to one with ordinary skill in the art.

The capacitor bank capacitance may be calculated relative to the inductance of the transformer primary (described below) so as to closely correlate to the resonant frequency of the capacitance attached to the transformer secondary (described below) for improvement in power transfer and preservation of optimal phase relationships. A capacitance of approximately 67 pF was used in the exemplary embodiment disclosed herein.

This method of transduction was tested using HV Mica Ceramic capacitors, HV Polymer capacitors, as well as HV MLCC (Multi-layer-ceramic capacitors). A 67pF HV MLCC bank, rated at approximately 120 kV, was used in the exemplary embodiment disclosed herein, due to superior performance in said embodiment with an additional benefit of being of extremely small size and low-weight.

Regulation: In order to constrain the operating voltage of the apparatus, regardless of the E-field strength and density, and thereby clearly define the parameters for selection of appropriate materials capable of reliable and safe operation under a plurality of variable conditions whilst allowing small size and weight of the apparatus, an operating voltage was arrived at by careful hypotheses formation, experimentation, test and measurement.

As a regulating element, an appropriate voltage-controlled switch element was selected, to allow for reliable and safe operation in a plurality of environments and environmental conditions, including but not limited to: various temperature and humidity levels, pressure levels (atmospheric or otherwise), presence of inert or explosive gases, different atmospheric conditions and altitudes, etc. Considerations for selecting the particular regulating element are disclosed as follows:

Mechanical and solid-state switch component were immediately ruled out as clearly inadequate for reasons readily familiar to one with ordinary skill in the art.

A calibrated air spark gap set to the appropriate distance (voltage), as well as an adjustable spark gap may serve well, but is inappropriate for the purposes of the apparatus disclosed herein for several reasons, including but not limited to: undue sensitivity to environmental factors (ie, humidity, gas composition of environment, ambient atmospheric pressure, etc.), inconsistent operation due to component wear (metal “sputtering”, etc.), EMI (electromagnetic interference) caused by spark discharges, potentially inadequate quenching, etc.

An appropriately rated liquid-filled discharge switch would function, but was not used due to various innate unsuitabilities, including but not limited to potential lack of practicality for sustained operation, for the purposes of the apparatus disclosed herein.

Appropriate fast, high-energy gas-filled or vacuum discharge switches (both triggered and untriggered) are ideal for the purposes of the exemplary embodiment disclosed herein. However, they can be extremely expensive and tend to have very limited lifetimes (ie, limited number of discharges).

Ultimately, readily available, very small, inexpensive, high-voltage plasma arrestors, sometimes referred to as “gas plasma arrestors” or simply “gas discharge tubes”, were selected and successfully used, in order to set the voltage at which the aforementioned HV E-field transduction capacitor bank would discharge into the transformer (described below). The discharge voltage was thereby set at a nominal 14.4 kV for the exemplary embodiment disclosed herein.

Additionally, the plasma arrestors were insulated using PTFE tubing, said PTFE tubing being wrapped with twenty turns of 18AWG insulated wire, said wrapping having proven effective for purposes including but not limited to suppression of EMI/RFI produced by the aforementioned capacitor-discharge pulses, capture of said EM and RF energies in a magnetic field induced by the aforementioned capacitor-discharge pulses passing through said 20-turn wire coil surrounding the PTFE tubing enclosing the plasma arrestors, which said induced magnetic field, upon collapsing will both cause ‘pulse-compression’ upon the energized plasma in said plasma arrestors, as well as returning current ordinarily dissipated to the surroundings, back into the apparatus.

Transformation: Any appropriate high-voltage transformer could be used for the exemplary embodiment disclosed herein, including but not limited to high-voltage pulse transformers, forward-converter, fly-back converter, fly-back transformer, capacitive discharge transformer, etc.

The following considerations need to be taken into account when specifying an appropriate transformer:

Must be capable of handling energy and power levels produced by regulated voltage pulses produced by the aforementioned transduction capacitor bank and regulation element, at various potential frequencies depending upon the E-field strength and density being processed, with appropriate primary:secondary step-down ratio, as well as appropriate primary:secondary inductance ratio.

The element must be capable of various frequency-ranges whilst efficiently transforming extremely fast discharge-waveform pulse rise and fall-time operation, ruling out various transformer materials and constructions, for example.

Air-core as well as “fly-back” type transformers were tested and may operate quite well, but were not used in the disclosed exemplary embodiment due to the stated design goal of avoiding or severely limiting EMI/EMP (electromagnetic-pulse) emission as well as mitigating the need for employing complex emission shielding strategies and methods.

Based upon the aforementioned considerations and extensive testing and measurement, a readily available, high quality, so-called “High Energy Ignition” transformer possessing the aforementioned necessary attributes was used in the exemplary embodiment disclosed herein.

The HV E-field, following aggregation into a voltage pulse as heretofore described, enters the transformer at the high-voltage side (primary) and is passed from the low-voltage (secondary) side of the transformer, thereby stepping the voltage pulse down.

Additionally, a plurality of plasma arrestors set at a nominal 21 6kV, insulated using PTFE tubing and wrapped with 20 turns of insulated 18 AWG wire as described above was connected between the primary terminals of the transformer for purposes including but not limited to similar functionality of a so-called “fly-back diode” in a conventional inductive circuit.

A ringing, pseudo-AC wave is induced in the low-voltage side of the transformer by the pulse entering the high-voltage side of the transformer.

Filtration: The stepped-down voltage-pulse is passed through filter capacitors on both the polarities of the low-voltage side (secondary) of the transformer, to the rectification stage, (described next).

For purposes of the exemplary embodiment disclosed herein, Metalized Polymer Film, 1 uF capacitors rated at 1 kV, were used.

Rectification: Efficient rectification of the transformer output is necessary to most effectively transfer the transduced and transformed energy to the storage/load.

Any rectification element following a rectification methodology that performs efficiently and effectively is suitable, including but not limited to half-wave rectification, synchronous rectification, low-voltage plasma rectification, etc.

A full wave bridge rectifier topology was used in the particular exemplary embodiments disclosed herein, which is not exclusive of any other well-performing rectification method. Several types of diodes were found to be quite capable for the exemplary embodiment disclosed herein. The criteria for selection of appropriate diodes are based upon the following:

A high-energy pulse wave output by the system heretofore described rings, displays resonant characteristics, contains multiple frequency harmonics, etc., as is known to one skilled in the art. Therefore, high-speed, robust diodes, with careful attention to low junction-capacitance are mandatory for this application. Lower forward-voltage drop of the diodes raises efficiency of the system.

Specifically, gold-bonded germanium diodes, Silicon rectifier diodes, FERD (field-effect rectifier diodes), and various high-speed SiC Schottky rectifier diodes were tested. All functioned well—excluding the Silicon diodes, unless used in a double-rectifier configuration (ie, two bridge rectifier configurations, back-to-back).

Furthermore, a low-voltage plasma rectification scheme was tested and yielded interesting results.

Ultimately, robust, readily available, high-speed 16A 600V SiC Schottky rectifier diodes were used in the exemplary embodiment disclosed herein.

Smoothing: The smoothing capacitor is used to smooth the DC output pulses. A conventional Metalized Polymer Film 1 uF capacitor rated at 1 kV was used in the exemplary embodiment disclosed herein.

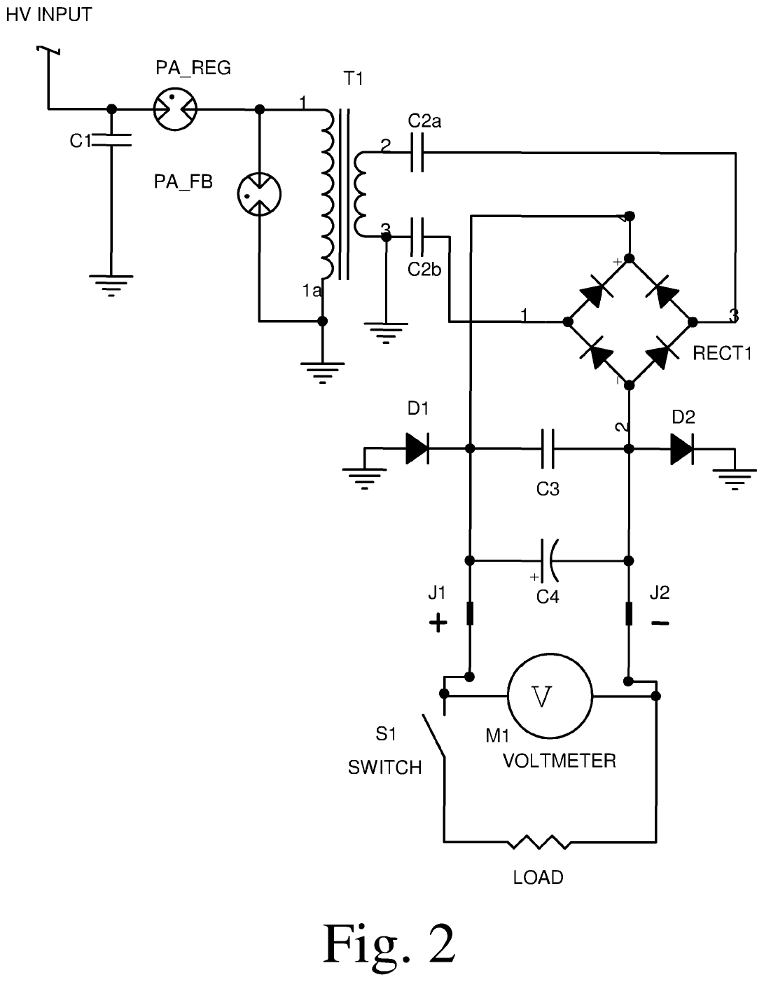

Signal-Reflection/Reactive Power Recovery: Upon construction, testing and careful analysis of the functioning apparatus, ultimately two 20A 100V Field-Effect Rectifier Diodes [FERD] were placed between the outputs from the aforementioned smoothing capacitor and the ground, in reversed polarity, as depicted in FIG. 2 of this disclosure, for purposes including but not limited to varying impedance compensation, recovering energy from signal reflections produced by the fast pulses produced by the system, as well for the purpose of phase modification for partial recovery of so-called Reactive Power, etc., resulting in performance enhancements.

Intermediate Output Storage: The device uses a bank of capacitors for intermediate output storage. For purpose of experimentation, various capacitors were banked, tested and measured.

Various types of capacitors were successfully tested.

Ultra-capacitors were banked (approximately 0.1 Farad rated at 50V) and functioned well, with an added benefit of being extremely compact and low-weight.

The aforementioned readily available ultra-capacitors were used for the exemplary embodiment disclosed herein.

Output: A standard halogen light-bulb fixture was connected to the output. 80 to 200 Watt 220V halogen bulbs were tested as loads, as well as for fully discharging the capacitor bank heretofore described when not in use.

A 220V, 80 W halogen bulb was used for the exemplary embodiment disclosed herein.

A schematic representation of an exemplary embodiment of the disclosed invention is depicted in FIG. 2.

The components depicted in FIG. 2 are specified as follows:

The HV INPUT is fed from an E-Field Source, which is then connected to one terminal of the Capacitor C1 (the other terminal is connected to ground). This capacitor, in the exemplary embodiment disclosed herein comprises several series-connected capacitors, for example totaling 120 kV nominal at approximately 67 pF, is the E-Field Transduction High-Voltage MLCC capacitor bank as described above.

The said terminal of Capacitor C1 connected to the HV INPUT is connected to the plasma arrestor PA_REG which in the exemplary embodiment disclosed herein comprises several 285 series-connected high-voltage plasma arrestors, for example totaling 14.4 kV nominal, for the purpose of regulating the operating voltage.

T1 is a Step-down Transformer, heretofore described. The plasma arrestor PA_FB which in the exemplary embodiment disclosed herein comprises several series-connected high-voltage plasma arrestors, for example totaling 21.6 kV nominal, is connected across T1 primary terminals labeled ‘1’ and ‘1a’, for purposes including but not limited to similar functionality of a so-called ‘fly-back diode’ in a conventional inductive circuit. Furthermore, plasma arrestor PA_FB protects both the Capacitor C1 and Step-down Transformer T1 from input over-voltages.

C2a and C2b are Filter Capacitors, for example being implemented specifically as 1 uF Metalized Polymer Capacitors rated at 1 kV, each having one terminal connected to one terminal of the Step-down Transformer T1, and the other terminals each connected to an input of the full wave bridge Rectifier RECT.

RECT is a full wave bridge Rectifier, for example being implemented by high-speed SiC [Silicon Carbide] Schottky diodes, 600V 16A.

C3 is a Smoothing Capacitor, for example being implemented using the Metalized Polymer Capacitor of 1 kV nominal at 1 uF

D1 and D2 are 20A 100V Field-Effect Rectifier Diodes, attached in reversed polarity to each terminal of capacitor C3.

C4 is the Intermediate Output Storage, which may be implemented using an ultra-capacitor bank of 50V and 0.1 F nominal.

J1 and J2 are Output terminals to the Load.

M1 is a voltmeter, connected across terminals J1 and J2, for the purpose of measuring the voltage accumulating in the Intermediate Output Storage C4 during operation of the exemplary embodiment disclosed herein.

S1 is a switch, which when closed, connects the LOAD comprising an 80 W, 220V halogen light-bulb in the exemplary embodiment disclosed herein, to the Intermediate Output Storage C4, which said Intermediate Output Storage C4 then discharges into. Furthermore, when closed, said switch S1 allows Intermediate Output Storage C4 to remain discharged when the apparatus is not being operated.

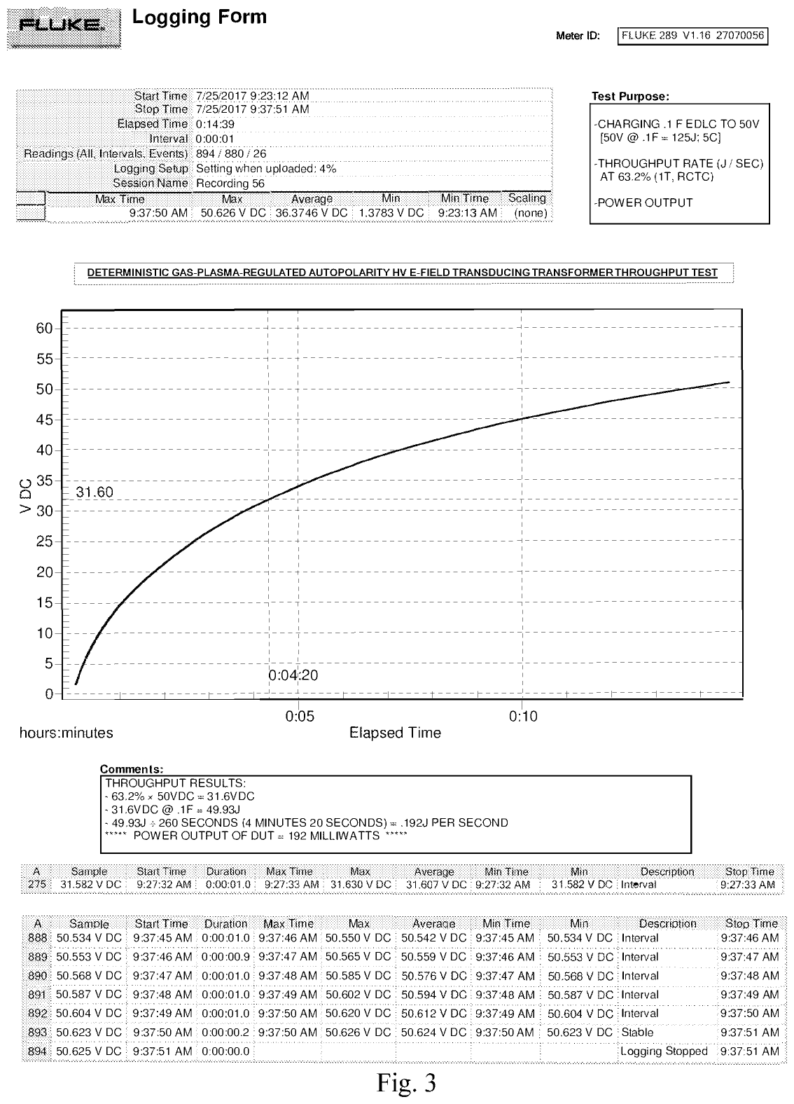

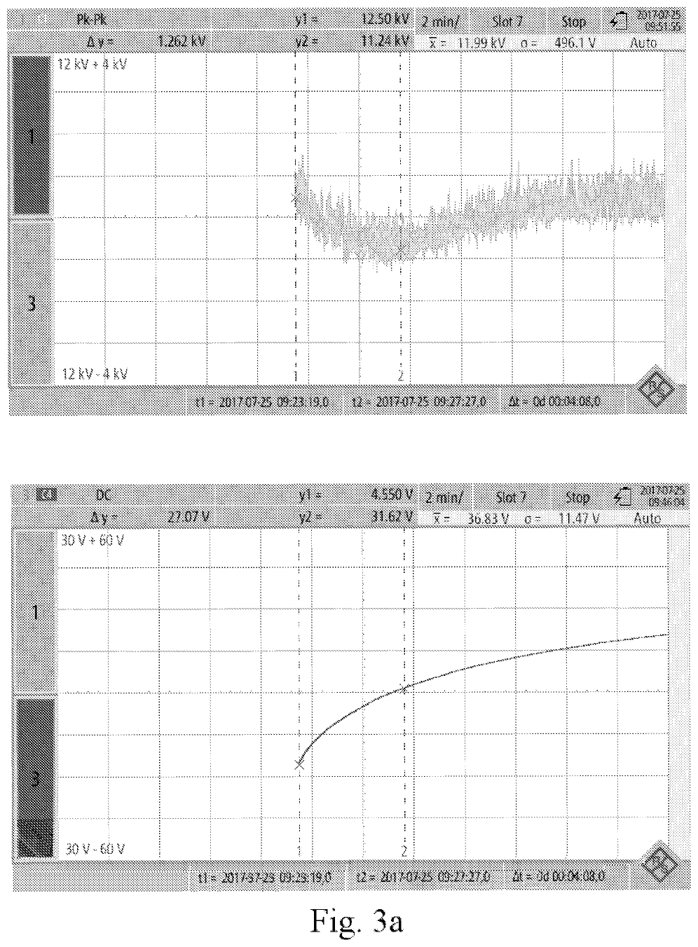

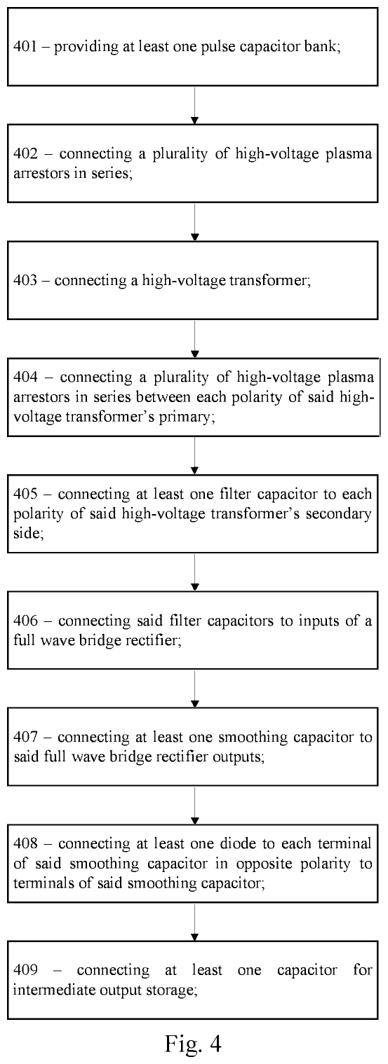

FIG. 3 depicts a measurement graph^{[1]} of the voltage accumulated in Intermediate Output Storage C4 as a function of elapsed time. The voltage is followed over a duration of 14 minutes and 39 ^{[1]}Instrument used: Fluke 289 True RMS Logging DMM; graph generated with “FlukeView Forms” Software seconds, and as will be apparent from the graph, a maximum of 50.626 VDC was developed in said time period.

For properly measuring functional performance parameters in the exemplary embodiment disclosed herein, a standard method for measuring so-called Response of First Order Systems, also commonly known as, “The 63.2 Percent Method” or “The RC Time Constant” was employed. As shown in FIG. 3, a graph cursor line was placed at 31.6V (50V×63.2%=31.6V), and another graph cursor line was placed on the time axis where said cursor line intersected the voltage curve measured at 31.6V, giving an elapsed time of 4 minutes and 20 seconds [260 seconds].

Using the formulas: W=(½)C×V² [where ‘C’ represents Capacitance and ‘V’ represents Voltage] provides ‘W’ [where ‘W’ represents Work; energy stored in Joules], and Q=C×V [where C represents Capacitance and ‘V’ represents Voltage] provides ‘Q’ [where ‘Q’ represents stored charge in Coulombs]. Substituting the values of the components and voltage obtained from the 330 exemplary embodiment disclosed herein during the measurement depicted in FIG. 3 provides the following results:

For the total of 50.626V:

C=0.1 Farad; V=50.626 Volts; W=(½) C×V²=(½)0.1×50.626²=128.1 Joules

Q=C×V=0.1×50.626=5.0626 Coulombs

For the RC Time Constant Measurement of 31.6V:

C=0.1 Farad; V=31.6 Volts; W=(½)C×V²=(½)0.1×31.6²=49.93 Joules

Q=C×V=0.1×31.6=3.16 Coulombs

An approximate average first-order power for the exemplary embodiment disclosed herein under the exemplary test conditions described above can be calculated as approximately:

49.93 Joules÷260 Seconds=0.192 Joules per Second, or 192 milliwatts.

FIG. 3a depicts an oscilloscope grap^{[2]} of the same measurement of the functioning exemplary embodiment disclosed herein recorded in FIG. 3, showing both the regulation of the High-Voltage input [top-half of FIG. 3A, ‘1’] and the simultaneous charging of the Intermediate Output Storage C4 [lower-half of FIG. 3A, ‘3’]. During the time period described above for charging the ^{[2]} Instrument used: Rohde&Schwarz RTH 1054 500 MHz-5 GS/s Isolated Digital Oscilloscope; graphic from screenshot.

Intermediate Output Storage C4 to 31.6V, the average regulated High-Voltage was approximately 12 kV. As heretofore described, this regulated High-Voltage was produced by charging the aforementioned Capacitor C1 of 67 pF, controlled by plasma arrestor PA_REG. Therefore using the same formulas as above, with the appropriate values:

C=67 picofarad; V=12 kV;

W=(½)C×V²=(½)[67×10⁻¹²]×12000²=0.004824 Joules

Q=C×V=[67×10⁻¹²]×12000=[804×10⁻⁹] Coulombs

The frequency for said regulated High-Voltage pulses was measured at approximately 48 Hertz.

An approximate Input Power can be calculated:

Input Power: 0.004824 Joules per pulse×48 pulses per second=0.2316 Joules per Second, or 231.6 milliwatts.

An approximate operating efficiency of an actual functional manifestation of the exemplary embodiment disclosed herein can be calculated:

Output Power÷Input Power=Efficiency (Percentage): 0.192 W÷0.2316 W=0.829=82.9% Efficiency.

FIG. 4 depicts a method for assembling a step-down transformer of the present invention. The method comprises steps of:

a. providing at least one pulse capacitor bank 401;

b. connecting a plurality of high-voltage plasma arrestors in series to said at least one pulse capacitor bank 402;

c. connecting a high-voltage transformer to said plurality of high-voltage plasma arrestors 403;

d. connecting a plurality of high-voltage plasma arrestors in series between primary terminals of said high-voltage transformer 404;

e. connecting at least one filter capacitor to each polarity of said high-voltage transformer's secondary side 405;

f. connecting said filter capacitors to a full wave bridge rectifier 406;

g. connecting at least one smoothing capacitor to said full wave bridge rectifier 407;

h. connecting at least one diode to each terminal of said smoothing capacitor(s), in polarity opposite to polarity of said terminal of said smoothing capacitor(s) 408;

i. connecting at least one capacitor for intermediate output storage 409;

For step 403, type of said high-voltage transformer is determined by at least some of the 380 following considerations: said transformer is capable of handling energy and power produced by said at least one pulse capacitor bank and said plurality of plasma arrestors, at various potential frequencies depending upon an E-field strength being processed, with appropriate primary/secondary step-down ratio, and be capable of various frequency-ranges as well as extremely fast pulse rise-time operation;

For step 401, the pulse capacitor bank, is rated at least twice of a voltage derived from said plurality of high-voltage plasma arrestors connected in step 402;

For step 401, capacitance of said pulse capacitor bank is relative to the inductance of a primary side of said high-voltage transformer of step 403, to closely correlate to a resonant frequency of capacitance attached to a secondary side of said transformer for improvement in power transfer and preservation of optimal phase relationships between transformer primary and secondary.

For step 404, voltage of said high-voltage plasma arrestors are rated at least thirty-percent higher than voltage rating of said high-voltage plasma arrestors connected in step 402;

For step 408, voltage of said diodes is rated at least twice of the voltage rating of said capacitor(s) for intermediate storage connected in step 409.

The foregoing description and illustrations of the embodiments of the invention has been presented for the purposes of illustration. It is not intended to be exhaustive or to limit the invention to the above description in any form.

Any term that has been defined above and used in the claims, should be interpreted according to this definition.

1. A step-down transformer for transformation of electric fields having varied voltage and current potentials, comprising:
a. at least one pulse capacitor bank, rated to at least twice of a voltage derived from said plurality of high-voltage plasma arrestors;
b. a plurality of high-voltage plasma arrestors connected in series, to said at least one pulse capacitor bank;
c. a high-voltage transformer connected to said plurality of high-voltage plasma arrestors;
d. a plurality of high-voltage plasma arrestors connected in series, between primary terminals of said high-voltage transformer;
e. at least one filter capacitor connected to each polarity of said high-voltage transformer's secondary side;
f. a rectification element connected to said filter capacitors;
g. at least one smoothing capacitor connected to said full wave bridge rectifier;
h. at least one diode connected to each terminal of said smoothing capacitor, in a polarity opposite to polarity of said terminal of said smoothing capacitor;
i. at least one capacitor for intermediate output storage;
wherein, type of said high-voltage transformer is determined by at least some of the following considerations: said transformer is capable of handling energy and power produced by said at least one pulse capacitor bank and said plurality of high-voltage plasma arrestors, at various potential frequencies depending upon an E-field strength being processed, with appropriate primary/secondary step-down ratio, and be capable of various frequency-ranges as well as extremely fast pulse rise-time operation;
further wherein, said plurality of high-voltage plasma arrestors in series, between primary terminals of said high-voltage transformer, is rated approximately thirty-percent higher than voltage rating of said plurality of high-voltage plasma arrestors in series connected to said pulse capacitor bank;
further wherein, capacitance of said pulse capacitor bank is relative to the inductance of a primary side of said high-voltage transformer, to closely correlate to a resonant frequency of capacitance attached to a secondary side of said transformer for improvement in power transfer and preservation of optimal phase relationships between transformer primary and secondary;
further wherein, said at least one diode(s) connected to each terminal of said smoothing capacitor, in polarity opposite to polarity of said terminal of said smoothing capacitor, are rated at least twice the voltage rating of said capacitor for intermediate storage.

2. The step-down transformer of claim 1, wherein said plurality of high-voltage plasma arrestors are insulated using PTFE tubing, being wrapped with twenty turns of 18AWG insulated wire.

3. The step-down transformer of claim 1, wherein said high-voltage transformer is a “High Energy Ignition” transformer.

4. The step-down transformer of claim 1, wherein said at least one filter capacitor is a Metalized Polymer Film capacitor.

5. The step-down transformer of claim 1, wherein said rectification element is a full bridge rectifier.

6. The step-down transformer of claim 1, wherein said smoothing capacitor is a Metalized Polymer Film capacitor.

7. The step-down transformer of claim 1, wherein said at least one diode that is connected to each terminal of said smoothing capacitor, is a Field-Effect Rectifier Diode.

8. A method for assembling a step-down transformer for transformation of electric fields having varied voltage and current potentials, comprising the steps of:
a. providing at least one pulse capacitor bank, rated to at least twice of a voltage derived from said plurality of high-voltage plasma arrestors;
b. connecting a plurality of high-voltage plasma arrestors in series, to said at least one pulse capacitor bank;
c. connecting a high-voltage transformer to said plurality of high-voltage plasma arrestors;
d. connecting a plurality of high-voltage plasma arrestors in series, between primary terminals of said high-voltage transformer;
e. connecting at least one filter capacitor to each polarity of said high-voltage transformer's secondary side;
f. connecting said filter capacitors to a rectification element;
g. connecting at least one smoothing capacitor to said full wave bridge rectifier;
h. connecting at least one diode to each terminal of said smoothing capacitor, in a polarity opposite to polarity of said terminal of said smoothing capacitor;
i. connecting at least one capacitor for intermediate output storage;
wherein, type of said high-voltage transformer is determined by at least some of the following considerations: said transformer is capable of handling energy and power produced by said at least one pulse capacitor bank and said plurality of high-voltage plasma arrestors, at various potential frequencies depending upon an E-field strength being processed, with appropriate primary/secondary step-down ratio, and be capable of various frequency-ranges as well as extremely fast pulse rise-time operation;
further wherein, said plurality of high-voltage plasma arrestors in series, between primary terminals of said high-voltage transformer, is rated approximately thirty-percent higher than voltage rating of said plurality of high-voltage plasma arrestors in series connected to said pulse capacitor bank;
further wherein, capacitance of said pulse capacitor bank is relative to the inductance of a primary side of said high-voltage transformer, to closely correlate to a resonant frequency of capacitance attached to a secondary side of said transformer for improvement in power transfer and preservation of optimal phase relationships between transformer primary and secondary;
further wherein, said at least one diode(s) connected to each terminal of said smoothing capacitor, in polarity opposite to polarity of said terminal of said smoothing capacitor, are rated at least twice the voltage rating of said capacitor for intermediate storage.

9. The method of claim 8, wherein said plurality of high-voltage plasma arrestors are insulated using PTFE tubing, being wrapped with twenty turns of 18AWG insulated wire.

10. The method of claim 8, wherein said high-voltage transformer is a “High Energy Ignition” transformer.

11. The method of claim 8, wherein said at least one filter capacitor is a Metalized Polymer Film capacitor.

12. The method of claim 8, wherein said rectification element is a full bridge rectifier.

13. The method of claim 8, wherein said smoothing capacitor is a Metalized Polymer Film capacitor.

14. The method of claim 8, wherein said at least one diode that is connected to each terminal of said smoothing capacitor, is a Field-Effect Rectifier Diode.
